(19) United States
(12) Patent Application Publication
(10) Pub. No.: US 2003/0140190 A1
(43) Pub. Date: Jul. 24, 2003

(54) Auto-SCSI termination enable in a CPCI hot swap system

(75) Inventors: Maire Mahony, Santa Clara, CA (US); Gerald R. Pelissier, Round Rock, TX (US)

Correspondence Address: Brian M. Berliner, O'MELVENY & MYERS LLP, 400 So. Hope Street, Los Angeles, CA, 90071-2899, US

(73) Assignee: SUN MICROSYSTEMS, INC.

(21) Appl. No.: 10/055,692

(22) Filed: Jan. 23, 2002

(51) Int. Cl. G06F 13/00; H05K 7/10

(52) U.S. Cl. 710/302

(57) ABSTRACT

A Compact Peripheral Component Interconnect (CPCI) system includes a circuit board with a front card (e.g., motherboard) coupled to a transition card via the circuit board. The CPCI system is adapted to provide for the dynamic replacement of the front card connected with a Small Computer System Interface (SCSI) device. The CPCI system includes a transition card that is adapted to provide the termination at the SCSI bus extremity (end) when its corresponding front card is removed. Preferably, the transition card allows for termination on its corresponding front card and not on the transition card when both the front card and the transition card are present (normal operating mode). The transition card's transition termination features are automatically enabled upon extraction of its corresponding front card and automatically disabled upon insertion of its corresponding front card. In the case that the front card is not at the extremity of the SCSI bus, it is possible to permanently disable the termination on the front card and/or the transition card by using override switches on the front card and/or the transition card.

### BACKGROUND OF THE INVENTION

1. Field of the Invention

The present invention relates to a Compact Peripheral Component Interconnect (CPCI) system. More particularly, the present invention relates to a CPCI system that is adapted for the dynamic replacement of a front card connected with a Small Computer System Interface (SCSI) device.

2. Description of Related Art

CPCI is a high performance industrial bus based on the standard PCI electrical specification in rugged 3U or 6U Eurocard packaging. CPCI is intended for application in telecommunications, computer telephony, real-time machine control, industrial automation, real-time data acquisition, instrumentation, military systems or any other application requiring high speed computing, modular and robust packaging design, and long term manufacturer support. Because of its high speed and bandwidth, the CPCI bus is particularly well suited for many high-speed data communication applications such as servers, routers, converters, and switches.

Compared to standard desktop PCI, CPCI supports twice as many PCI slots (typically 8 versus 4) and offers an ideal packaging scheme for industrial applications. Conventional CPCI cards are designed for front loading and removal from a card cage. The cards are firmly held in position by their connector, card guides on both sides, and a faceplate that solidly screws into the card cage. Cards are mounted vertically allowing for natural or forced air convection for cooling. Also, the pin-and-socket connector of the CPCI card is significantly more reliable and has better shock and vibration characteristics than the card edge connector of the standard PCI cards.

Conventional CPCI defines a backplane environment that is typically limited to eight slots. More specifically, the bus segment of the conventional CPCI system is limited to eight slots, in which front cards (e.g., motherboards) and mating transition cards are installed. Typically the front card provides substantially all features and functions (i.e., clocking, arbitration, configuration, and interrupt processing) of the CPCI system and the transition card allows access to these features and functions by providing ports, such as Small Computer System Interface (SCSI) ports.

Most CPCI front cards (e.g., motherboards) in the system slot feature SCSI support. SCSI buses require termination at the extremities (or ends). Termination simply means that each end of the SCSI bus is closed either via a resistor circuit or an active terminator. (Active termination which incorporates a small voltage regulator for better impedance matching is preferred for most SCSI speed specifications and is especially preferred for Ultra SCSI speed specification.) If the bus were left open (not terminated), electrical signals sent down the bus may reflect back and interfere with communication between SCSI devices and the SCSI controller. Only two terminators are used: one at each end of the SCSI bus. In the CPCI system, the front card (e.g., motherboard) is typically at the extremity (at the end) of an SCSI bus and provides termination. Termination is not allowed at any point other than at the extremities. When the front card (e.g., motherboard) is present and terminating the SCSI bus, termination is not allowed on the transition card. The problem arises when a CPCI front card (e.g., motherboard) is hot swap extracted from the CPCI system because termination of the SCSI bus is lost.

Accordingly, it would be desirable to provide a CPCI system that is adapted to provide for termination at an SCSI bus extremity while a front card is dynamically replaced.

### SUMMARY OF THE INVENTION

The present invention relates to a CPCI system that is adapted to provide for the dynamic replacement of a front card (e.g., motherboard) connected with an SCSI device. The CPCI system includes a transition card that is adapted to provide the termination at the SCSI bus extremity when its corresponding front card is removed. Preferably, the transition card allows for termination on its corresponding front card and not on the transition card when both the front card and the transition card are present (normal operating mode). It would be desirable to provide a transition card with transition termination features that are automatically enabled upon extraction of its corresponding front card and automatically disabled upon insertion of its corresponding front card. Optionally, in the case that the front card is not at the extremity of the SCSI bus, it is possible to permanently disable the termination on the front card and/or the transition card by using override switches on the front card and/or the transition card. The present invention provides the important advantage of not having to shut down the system during the replacement process.

In an embodiment of the invention, a Compact Peripheral Component Interconnect (CPCI) system includes a circuit board with a front card coupled to a transition card via the circuit board. A Small Computer System Interface (SCSI) bus is connected to the transition card. The SCSI bus has a first end and a second end. An SCSI device is connected to the first end of the SCSI bus. When the front card is disconnected from the CPCI system, the transition card provides a termination at the second end of the SCSI bus.

In another embodiment of the invention, a CPCI system has a circuit board with a plurality of connectors affixed to the circuit board. A front card is coupled to a transition card via the plurality of connectors. An SCSI bus is connected to the transition card. The SCSI bus has a first end and a second end. An SCSI device is connected to the first end of the SCSI bus. When the front card is disconnected from the CPCI system, the transition card provides a termination at the second end of the SCSI bus.

In a further embodiment of the invention, a CPCI system includes a circuit board. First, second, third, fourth and fifth connectors are affixed to the circuit board. A front card is coupled to a transition card via the third, fourth and fifth connectors. An SCSI bus is connected to the transition card. The SCSI bus has a first end and a second end. An SCSI device is connected to the first end of the SCSI bus. A first time-separated power domain is provided to the first, second and third connectors. The first and second connectors provide the first power domain to the front card and the third connector provides the first power domain to the transition card. The first power domain can be provided to the transition card only when the front card is connected to the third connector. The transition card uses the first power domain to determine when to provide a termination to the second end of the SCSI bus.

In yet another embodiment of the invention, a first time-separated power domain is provided to a front card. The first time-separated power domain is provided to a transition card only if the front card is coupled to the transition card. The transition card provides a termination at a Small Computer System Interface (SCSI) bus connected to the transition card only if the first time-separated power domain is not being provided to the transition card. The front card provides the termination at the SCSI bus if the first time separated power domain is being provided to the transition card.

A more complete understanding of the present invention will be afforded to those skilled in the art, as well as a realization of additional advantages and objects thereof, by a consideration of the following detailed description of the embodiment. Reference will be made to the appended sheets of drawings which will first be described briefly.

### BRIEF DESCRIPTION OF THE DRAWINGS

The drawings illustrate the design and utility of preferred embodiments of the invention. The components in the drawings are not necessarily to scale, emphasis instead being placed upon illustrating the principles underlying the embodiment. Moreover, in the drawings like reference numerals designate corresponding parts throughout the different views.

FIG. 1 is an exploded perspective view of a CPCI chassis system according to an embodiment of the invention;

FIG. 2(a) is a perspective of a transition card according to an embodiment of the invention;

FIG. 2(b) is a detailed view of an optional termination switch that may be incorporated into the transition card shown in FIG. 2(a);

FIG. 3 shows the form factors that are defined for the CPCI front card;

FIG. 4 is a front view of a backplane having eight slots with five connectors each;

FIG. 5(a) shows a front view of another CPCI backplane;

FIG. 5(b) shows a back view of the backplane of FIG. 5(a);

FIG. 6 shows a side view of the backplane of FIGS. 5(a) and 5(b);

FIG. 7(a) shows a front view of a pin out arrangement of the connectors of a slot;

FIG. 7(b) shows a back view of the pin out arrangement of the connectors of the slot of FIG. 7(a);

FIG. 8 shows a hot swappable CPCI system for detecting the presence of a hot swappable front card;

FIG. 9 is another exploded perspective view of a CPCI chassis system connected with a Small Computer System Interface (SCSI) device according to an embodiment of the invention;

FIG. 10 is a block diagram that illustrates a distribution of an EARLY POWER domain and a BACKEND POWER domain;

FIG. 11 is a block diagram that illustrates a distribution of an EARLY POWER domain to a transition card via its corresponding front card according to an embodiment of the invention; and

FIG. 12 is a block diagram that illustrates a logic that determines when a transition card should provide for termination according to an embodiment of the invention.

### DETAILED DESCRIPTION

The present invention relates to a CPCI system that is adapted to provide for the dynamic replacement of a front card (e.g., motherboard) connected with an SCSI device. In a conventional CPCI system, dynamic replacement of the front card is not allowed (i.e., when a CPCI front card is hot swap extracted from the CPCI system, termination of the SCSI bus is lost). Thus, the conventional CPCI system must shut

down during replacement of the front card connected with an SCSI device. Accordingly, the present invention satisfies the need for a CPCI system that continues to provide for termination at an SCSI bus extremity while a front card supporting an SCSI device is dynamically replaced, since this would allow the CPCI system to continue running even through the front card is being replaced.

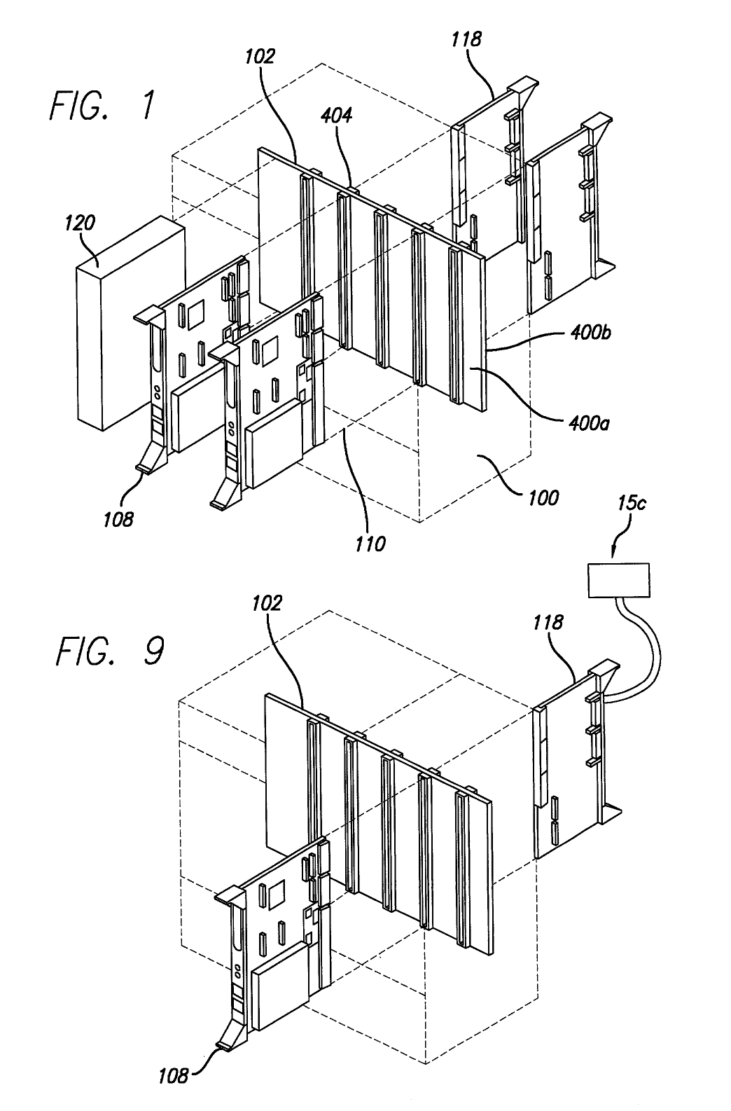

Referring to FIG. 1, there is shown an exploded perspective view of a CPCI chassis system as envisioned in a preferred embodiment of the present invention. The chassis system 100 includes a CPCI circuit board referred to in the conventional CPCI system as a passive backplane 102 since the circuit board is located at the back of the chassis 100 and front cards (e.g., motherboards) can only be inserted from the front of the chassis 100. The front side 400a of the backplane 102 has slots provided with connectors 404. A corresponding transition card 118 is coupled to the front card 108 via backplane 102. The backplane 102 contains corresponding slots and connectors (not shown) on its backside 400b to mate with transition card 118. In the chassis system 100 that is shown, a front card 108 may be inserted into appropriate slots and mated with the connectors 404. For proper insertion of the front card 108 into the slot, card guides 110 are provided. This CPCI chassis system 100 provides front removable front cards (e.g., motherboards) and unobstructed cooling across the entire set of front cards. The backplane 102 is also connected to a power supply 120 that supplies power to the CPCI system.

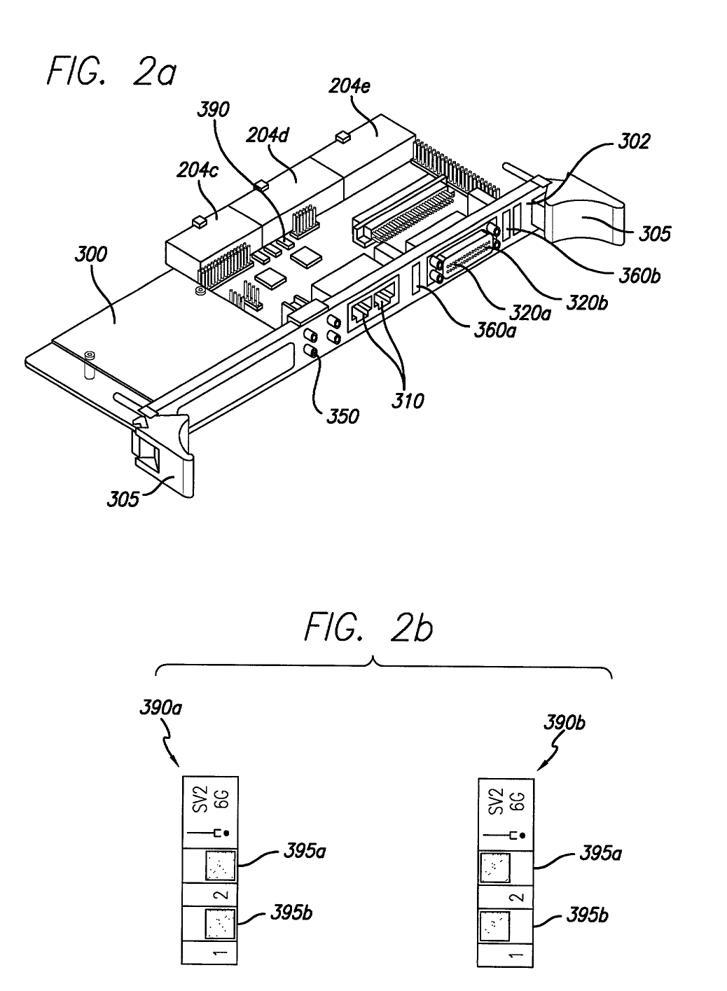

Referring to FIG. 2a, according to a preferred embodiment of the present invention, the rear transition card 300 has connectors 204c-204e, a rear plate interface 302 and ejector/injector handles 305. In this preferred embodiment, two ejector/injector handles 304 are used. Connectors 204c-204e are designed to be coupled to the connectors on a corresponding front card via a backplane (similar to the backplane 102 shown in FIG. 1). The rear plate interface 302 has a plurality of rear input/output (I/O) ports. Preferably, the ports comprise two Ethernet ports 310, an SCSI port 320a, an SCSI port 320b, a parallel port (not shown), two serial ports 350 and two Universal Serial Bus (USB) ports 360a-360b. Accordingly, the rear transition card 300 supplies the rear I/O ports to support additional peripherals (e.g., an SCSI device) for the CPCI system and should be fully compatible with its corresponding CPCI front card. In addition, the rear transition card 300 should be consistent with the PICMG CPCI standard and compliant with IEEE 1101.1 or IEEE 1101.10.

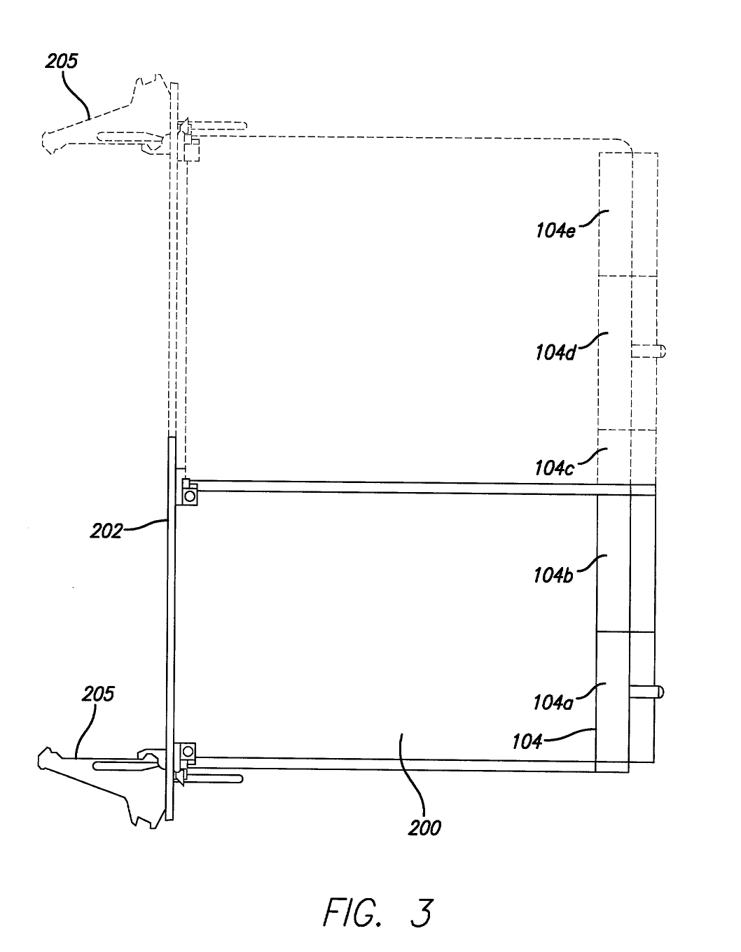

Referring to FIG. 3, there are shown the form factors defined for the CPCI front card (e.g., motherboard), which is based on the PICMG CPCI industry standard (e.g., the standard in the PICMG 2.0 CPCI specification). As shown in FIG. 3, the front card 200 has a front plate interface 202 and ejector/injector handles 205. The front plate interface 202 is consistent with PICMG CPCI packaging and is compliant with IEEE 1101.1 or IEEE 1101.10. The ejector/injector handles should also be compliant with IEEE 1101.1. Two ejector/injector handles 205 are used for the 6U front cards in the present invention. The connectors 104a-104e of the front card 200 are numbered starting from the bottom connector 104a, and the 6U front card size is defined, as described below.

The dimensions of the 3U form factor are approximately 160.00 mm by approximately 100.00 mm, and the dimensions of the 6U form factor are approximately 160.00 mm by approximately 233.35 mm. The 3U form factor includes two 2 mm connectors 104a-104b and is the minimum as it accommodates the full 64 bit CPCI bus. Specifically, the 104a connectors are reserved to carry the signals required to support the 32-bit PCI bus; hence no other signals may be carried in any of the pins of this connector. Optionally, the 104a connectors may have a reserved key area that can be provided with a connector “key,” which is a pluggable plastic piece that comes in different shapes and sizes, so that the add-on card can only mate with an appropriately keyed slot. The 104b connectors are defined to facilitate 64-bit transfers or for rear panel I/O in the 3U form factor. The 104c-104e connectors are available for 6U systems as also shown in FIG. 3. The 6U form factor includes the two connectors 104a-104b of the 3U form factor, and three additional 2 mm connectors 104c-104e. In other words, the 3U form factor includes connectors 104a-104b, and the 6U form factor includes connectors 104a-104e. The three additional connectors 104c-104e of the 6U form factor can be used for secondary buses (i.e., Signal Computing System Architecture (SCSA) or MultiVendor Integration Protocol (MVIP) telephony buses), bridges to other buses (i.e., Virtual Machine Environment (VME) or Small Computer System Interface (SCSI)), or for user specific applications. Note that the CPCI specification defines the locations for all the connectors 104a-104e, but only the signal-pin assignments for the CPCI bus portion 104a and 104b are defined. The remaining connectors are the subjects of additional specification efforts or can be user defined for specific applications, as described above.

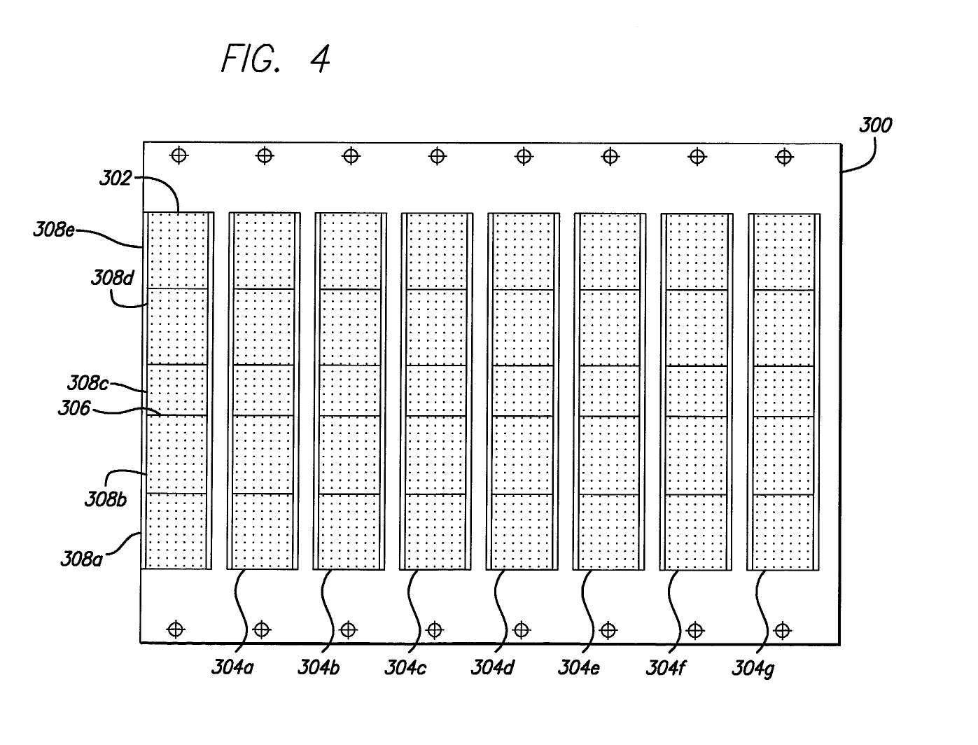

Referring to FIG. 4, there is shown a front view of a 6U backplane having eight slots. A CPCI system includes one or more CPCI bus segments, where each bus segment typically includes up to eight CPCI card slots. Each CPCI bus segment includes at least one system slot 302 and up to seven peripheral slots 304a-304g. The CPCI front card for the system slot 302 provides arbitration, clock distribution, and reset functions for the CPCI peripheral cards on the bus segment. The peripheral slots 304a-304g may contain simple cards, intelligent slaves and/or PCI bus masters.

The connectors 308a-308e have connector-pins 306 that project in a direction perpendicular to the backplane 300, and are designed to mate with the front side “active” cards (“front cards”), and “pass-through” its relevant interconnect signals to mate with the rear side “passive” input/output (I/O) card(s) (“rear transition cards”). In other words, in the conventional CPCI system, the connector-pins 306 allow the interconnected signals to pass-through from the front cards, such as the motherboards, to the rear transition cards.

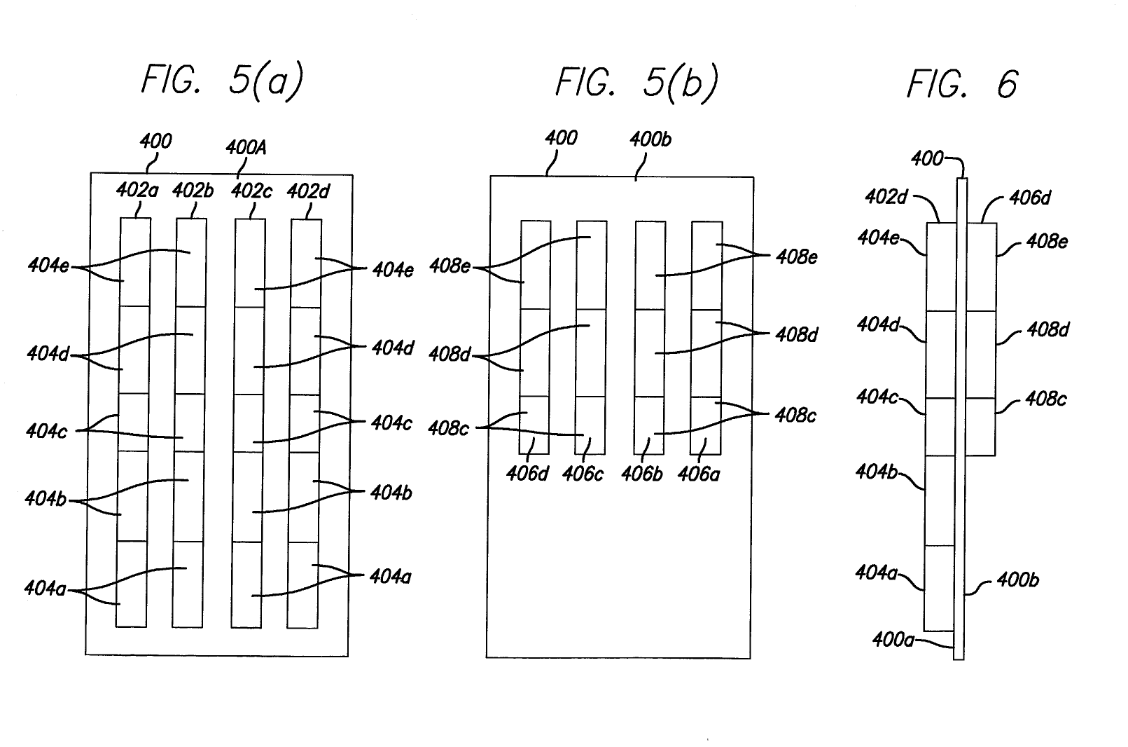

Referring to FIGS. 5(a) and 5(b), there are shown respectively a front and back view of a CPCI backplane in another 6U form factor embodiment. In FIG. 5(a), four slots 402a-402g are provided on the front side 400a of the backplane 400. In FIG. 5(b), four slots 406a-406g are provided on the back side 400b of the backplane 400. Note that in both FIGS. 5(a) and 5(b) only four slots are shown instead of eight slots as in FIG. 4.

Further, it is important to note that each of the slots 402a-402d on the front side 400a has five connectors 404a-404e while each of the slots 406a-406d on the back side 400b has only three connectors 408c-408e. This is because the 404a connectors are provided for 32 bit PCI and connector keying and the 404b connectors are typically only for I/O in the 3U form factor. Thus, in the 6U form factor they do not typically have I/O connectors to their rear. Accordingly, the front cards that are inserted in the front side slots 402a-402d only transmit signals to the rear transition cards that are inserted in the back side slots 406a-406d through front side connectors 404c-404e.

Referring to FIG. 6, there is shown a side view of the backplane of FIGS. 5(a) and 5(b). As shown in FIG. 6, slot 402d on the front side 400a and slot 406d on the back side 400b are arranged to be substantially aligned so as to be back to back. Further, slot 402c on the front side 400a and slot 406c on the backside 400b are arranged to be substantially aligned, and so on. Accordingly, the front side connectors 404c-404e are arranged back-to-back with the back side connectors 408c-408e. Note that the front side connector 404a-404b does not have a corresponding back side connector. It is important to note that the system slot 402a is adapted to receive the front card having a CPU; the signals from the system slot 402a are then transmitted to corresponding connector-pins of the peripheral slots 402b-402d. Thus, the preferred CPCI system can have expanded I/O functionality by adding peripheral front cards in the peripheral slots 402b-402d.

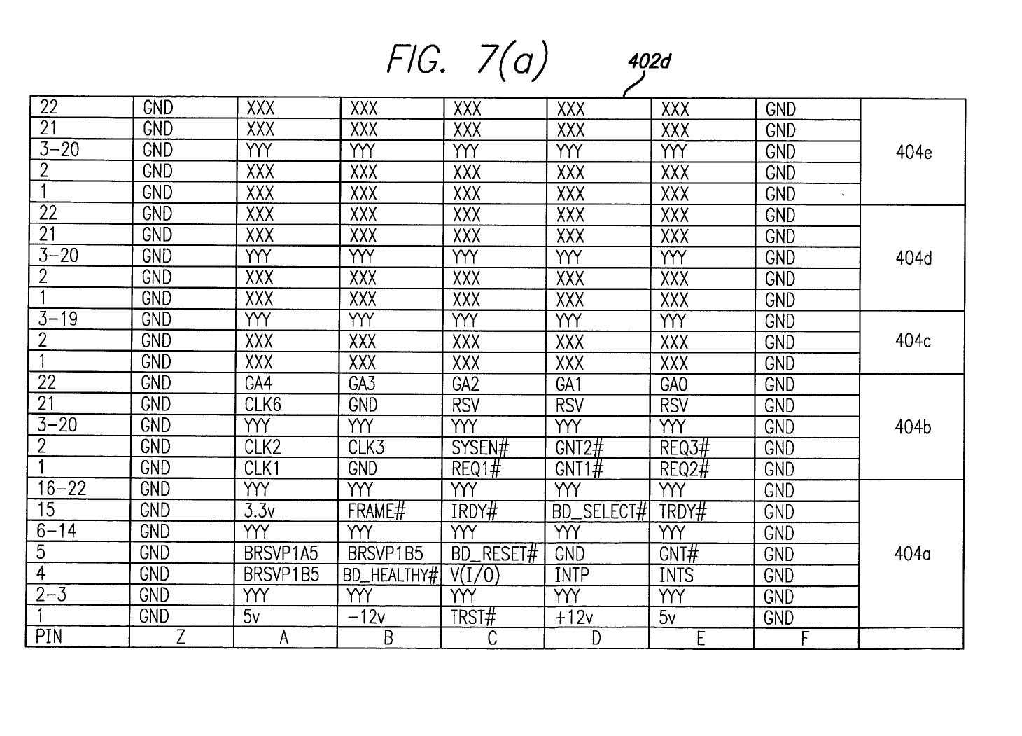

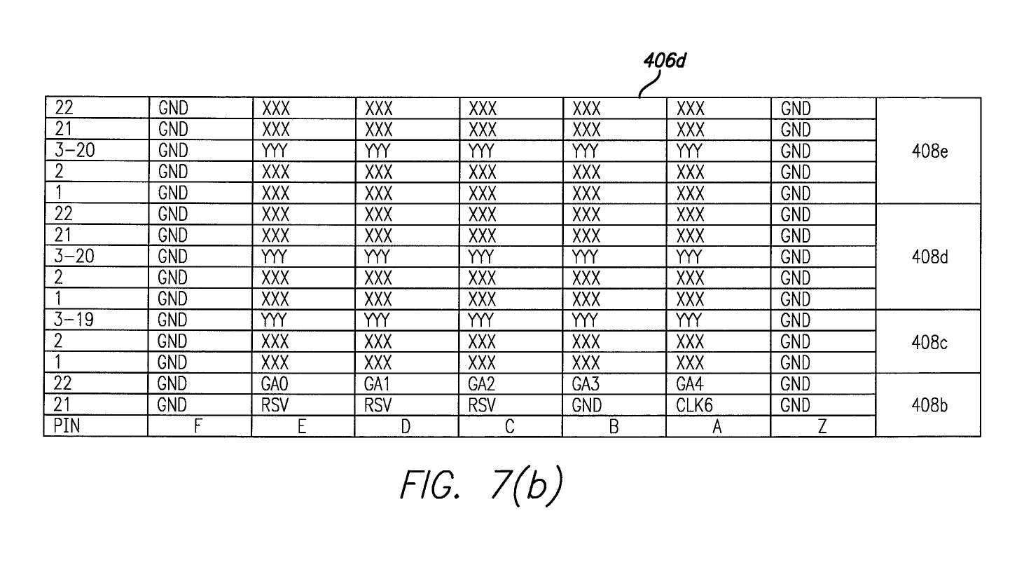

FIGS. 7(a) and 7(b) illustrate a pin out arrangement of the connectors in a CPCI system. Specifically, FIG. 7(a) shows a front view of a conventional pin out arrangement of the connectors of a slot. Referring to FIG. 7(a), there are shown connectors 404a-404e of slot 402d. The connector-pins are arranged in a column and row configuration. Each of the connectors 404a-404e has seven columns of pins, which are designated as Z, A, B, C, D, E, and F going from left to right. Each of the connectors 404a-b and 404d-e also has twenty-two rows of connector-pins. Connector 404c has nineteen rows of connector-pins.

As shown in FIG. 7(a), all of the connector-pins in the Z and F columns are connected to a ground layer GND in the backplane. The connector-pins of the other columns A, B, C, D, and E are connected to various other signals including ground.

Note that in FIG. 7(a), the connector-pins having XXX or YYY designations do not mean that those pins share the same signals, respectively. Instead, the XXX or YYY designations are provided to show that these connector-pins are defined to carry various signals, including CPCI signals, that are not particularly relevant to the present invention, and thus are not specifically shown in FIG. 7(a). Note that only connectors 404a-404c carry CPCI signals. Note also that the other slots 402a-402c have a similar pin out arrangement as shown in slot 402d of FIG. 7(a).

FIG. 7(b) shows a back view of a pin out arrangement of the connectors of a slot. Referring to FIG. 7(b), there are shown connectors 408c-408e of slot 406d. Note that the back view shows only three connectors instead of five. This is because, as shown in FIGS. 5(a) and 5(b), the front side of the backplane has five connectors while the back side of the backplane has three connectors. Further, the column arrangement of the connector-pins is designated as F, E, D, C, B, A, and Z going from left to right. This is because the connector-pins of slots 402d and 406d are straight-pass through pins, and so the column designations are mirror images with respect to each other. For example, the connector-pin located at column A, row 2 of connector 404c is the same connector-pin located at column A, row 2 of connector 408c. Also, similar to FIG. 7(a), connector-pins located at columns F and Z in FIG. 7(b) are connected to a ground layer GND in the backplane. Likewise, connector-pins of columns A, B, C, D, and E are connected to various signals, as shown in FIG. 7(a).

More specifically, the Hot Swap/HA specification defines the connector-pin located at column D, row 15 of connector 404(a) to be a BD_SELECT# pin. Other relevant connector-pins of connector 404a include a BD_HEALTHY# pin, which is located at column B, row 4, and a BD_RESET# pin, which is located at column C, row 5. The significance of these connector-pins in the Hot Swap/HA specification is discussed in more detail below.

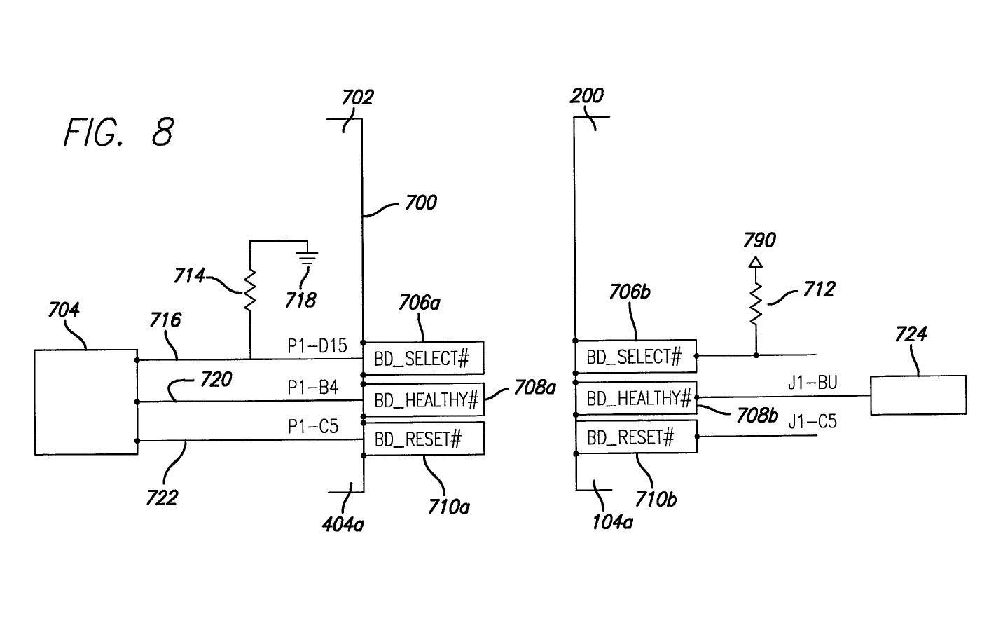

FIG. 8 shows a hot swappable CPCI system for detecting the presence of a hot swappable front card. Referring to FIG. 8, a CPCI backplane 700 has a connector 404a in a slot 702, and a hot swap controller 704 coupled to the backplane 700. The connector 404a has the BD_SELECT# 706a, BD_HEALTHY# 708a, and BD_RESET# 710a connector-pins, which are of male-type, connected to the hot swap controller 704. Note that the BD_SELECT# line 716 is connected to a “weak-pull-down” resistor 714 that is connected to a ground layer 718 in the backplane 702. A front card 200 has corresponding BD_SELECT# 706b, BD_HEALTHY# 708b, and BD_RESET# 710b connector-pins, which are of female-type, with the BD_SELECT# pin 706b being connected to a power domain (e.g., a voltage source) or more specifically an Early Power Domain 790 through a pull-up resistor 712. The BD_SELECT# line 716 is an input/output line and is defined to provide a signal to the hot swap controller 704 such that the controller 704 knows whether a hot swappable front card has been inserted in a particular slot. Further, the hot swap controller 704 performs the powering up/down of the hot swappable front card using this line 716. The BD_HEALTHY# pin 708b is connected to an internal power supply 724 in the front card 200. Accordingly, the BD_HEALTHY# line 720 is a hot swap controller input line and is used to indicate to the hot swap controller 704 whether or not the board is defective. The BD_RESET# line 722 is an input/output line and is used by the hot swap controller 704 to reset the front card if it is to remain in a backup mode. All of the above described functions of the BD_SELECT# BD_HEALTHY#, and BD_RESET# lines are described in more detail below.

Specifically, when the hot swappable front card 200 is inserted into a slot of the backplane 702 such that the connectors 404a and 104a mate, the BD_SELECT# pin 706a is pulled up to the voltage level of the BD_SELECT# pin 706b. This pull-up on the BD_SELECT# pin 706a is detected by the hot swap controller 704 such that the hot swap controller 704 senses that a hot swappable front card 200 has been inserted in the particular slot 702. The hot swap controller 704 then drives the BD_SELECT# line 716 low so as to allow the front card to power up. Then, the hot swap controller 704 examines the BD_HEALTHY# line 720 to determine if the inserted front card 200 is healthy. This determination is made by sensing the voltage level from the internal power supply 724. The hot swap controller then drives the BD_RESET# line 722 high to release the front card from the reset mode and to connect to the system, or if the front card is a backup board, then the BD_RESET# line 722 is driven low to maintain the front card 200 in the reset mode until backup is needed from the front card 200.

Referring now back to FIG. 1, the front card 108 (e.g., motherboard) is preferably a Hot Swap/HA front card described above. In addition, the front card 108 of the present invention features dual SCSI support. As previously mentioned, SCSI buses require termination at the extremities. In the CPCI system, the front card 108 is typically at the extremity of an SCSI bus and provides the termination. Termination is only allowed at the extremities. In normal operating mode, when the front card 108 is present and is terminating the SCSI bus, termination is not needed and should not occur on the transition card 118. Nevertheless, a problem arises when the CPCI front card 108 is hot swap extracted from the CPCI system since termination of the SCSI bus is lost. Because of the termination problem, the conventional CPCI system must be shut down prior to extraction of the front card connected with an SCSI device. Such is the case even when removing a hot swappable front card.

Referring to FIG. 9, in the CPCI system adapted for dynamic replacement of the front card connected with an SCSI device, the transition card 118 will provide for the termination at the SCSI bus extremity when its corresponding front card 108 is removed. The transition card 118 does not provide termination when both the front card 108 and the transition card 118 are present (normal operating mode). Preferably, the transition termination features of transition card 118 are automatically enabled upon extraction of its corresponding front card 108 and automatically disabled upon insertion of its corresponding front card 108.

Specifically, in normal operation, the front card 108 is coupled to its corresponding transition card 118 via backplane 102. With the front card 108 installed and connected with an SCSI device 150 through transition card 118, the front card 108 is at the extremity (the end) of the SCSI bus and provides termination. Termination on the transition card 118 is not needed and thus is disabled. In the event the front card 108 is hot swap extracted, the transition card 118 features auto-detect logic to automatically detect that the front card 108 is no longer present in the system and immediately performs the action of terminating the SCSI bus or buses. If and when the front card 108 is re-inserted to the system, the transition card 118 ceases to perform the function of terminating the SCSI bus and allows the front card 108 to resume the role of providing termination at the SCSI bus extremity.

FIGS. 10-12 show how the auto-detect logic automatically detects when the transition card's front card is or is not present and when the transition card should provide for termination. Referring to only to FIG. 10, the Hot Swap/HA front card of the present invention features two time-separated power domains. An EARLY POWER domain 900 is available at initial power on and is provided by the backplane 102. This power domain 900 is used to power the hot swap controller (System Management Controller or SMC) logic 910 which, as previously described, determines the health of the system. If the system is healthy, the controller (SMC) logic 910 turns on a power module 920 to provide for BACKEND POWER domain 930 to the main logic of the front card 108 and to the transition card 118 through CPCI connectors 404c-404e. Connectors 404c-404e are the only ones that provide the two power domains to transition card 118.

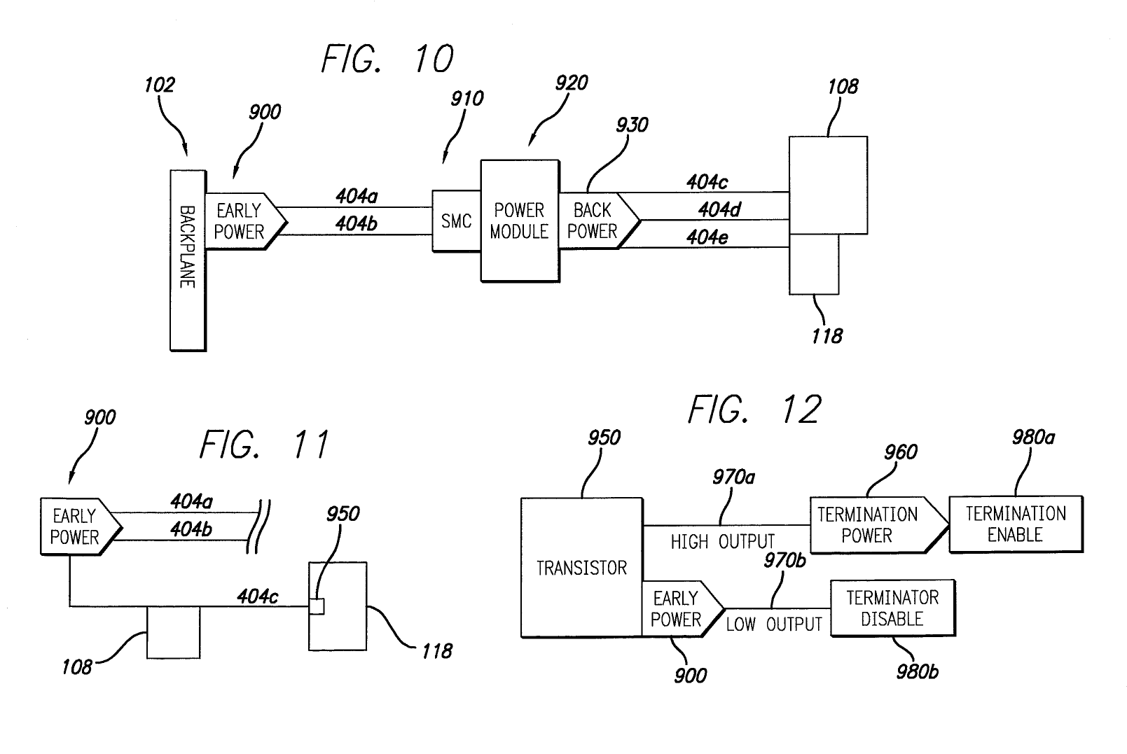

Referring now to FIGS. 10 and 11, EARLY POWER 900 is usually only provided from the backplane 102 through CPCI connectors 404a-404b, which only provide power domains to the front card 108. In FIG. 11, however, the front board 108 of the present invention provides a pin out on CPCI connector 404c to feed EARLY POWER 900 to the transition card 118, which powers the auto-detect logic of the transition card 118.

Referring now to FIG. 12, this auto-detect logic works because EARLY POWER 900 is no longer fed through 404c to the transition card's auto-detect logic when the front card 108 is hot extracted from a system. When 404c EARLY POWER 900 is removed, an auto-detect transistor 950 in the auto-detect logic switches off and the auto-detect transistor output is pulled high 970a to SCSI Termination POWER 960. SCSI termination is enabled 980a on the transition card 118 when the auto-detect transistor output is high 970a. When the front card 108 is hot inserted back into the system, EARLY POWER 900 is again fed through 404c to the transition card's “autodetect logic.” When 404c EARLY POWER 900 is restored, the auto-detect logic switches on, the auto-detect transistor output goes low 970b and SCSI termination is once again disabled 980b on the transition card 118.

Optionally, referring now to FIGS. 2(a)-2(b), in the event that the front card 300 is not at the extremity of the SCSI bus, it is possible to use an SCSI termination switch 390 on the transition card 300 to disable the auto-detect logic so that termination can never be enabled on the transition card 300. In this embodiment, terminal switch 390 includes a switch 390a for SCSI port 320a and switch 390b for SCSI port 320b. As an example in operation, referring now only to FIG. 2(b), switch sitting 390a shows a sitting when neither the bus connected to SCSI port 320a nor SCSI port 320b are terminated at the transition card 300. Switch sitting 390b shows a sitting where both the bus connected to SCSI port 320a and SCSI port 320b may be terminated on the transition card (i.e., in this sitting 390b, termination at the transition card depends on whether its corresponding front card is present in the system). A similar SCSI termination switch can also be featured on the front card to disable the termination features on the front card.

Finally, it should be noted that when the front card status is “not healthy,” the front card still provides SCSI bus termination (assuming the SCSI termination switch is enabled); this is why EARLY POWER, and NOT BACKEND POWER, is used to power the auto-detect logic.

Having thus described embodiments of the present invention, it should be apparent to those skilled in the art that certain advantages of the described system have been achieved. It should also be appreciated that various modifications, adaptations, and alternative embodiments thereof may be made within the scope and spirit of the present invention. For example, a CPCI system adapted for dynamic replacement of a front card connected with an SCSI device has been illustrated, but it should be apparent that the inventive concepts described above would be equally applicable to other types of buses and computer systems. The invention is further defined by the following claims.

What is claimed is:

1. A Compact Peripheral Component Interconnect (CPCI) system comprising:
a circuit board;
a front card coupled to a transition card via said circuit board;
a Small Computer System Interface (SCSI) bus connected to said transition card, said SCSI bus having a first end and a second end; and
an SCSI device connected to said first end of said SCSI bus, wherein during a period when said front card is disconnected from said CPCI system said transition card provides a termination at said second end of said SCSI bus.

2. The CPCI system of claim 1, wherein during normal operation when said front card is connected with said CPCI system, said front card provides the termination at said second end of said SCSI bus and said transition card does not provide the termination.

3. The CPCI system of claim 2, wherein during the period when said front card is disconnected from said CPCI system, said transition card automatically provides the termination.

4. The CPCI system of claim 3, wherein when said front card is reconnected with said CPCI system, said transition card automatically does not provide the termination.

5. The CPCI system of claim 1, further comprising a plurality of peripheral cards connected to said circuit board.

6. The CPCI system of claim 5, wherein said plurality of peripheral cards are in communication with said front card.

7. The CPCI system of claim 6, wherein each of said plurality of peripheral cards is coupled to a corresponding peripheral transition card via said circuit board.

8. The CPCI system of claim 1, wherein said front card is presented with a first time-separated power domain and a second time-separated power domain.

9. The CPCI system of claim 8, wherein said first time-separated power domain is provided to said transition card only when said front card is coupled to said transition card.

10. The CPCI system of claim 9, wherein said transition card uses said first time-separated power domain to determine when to provide the termination to said second end of said SCSI bus.

11. The CPCI system of claim 1, further comprising a switch for preventing said transition card from providing the termination.

12. The CPCI system of claim 1, further comprising a switch for preventing said front card from providing the termination.

13. The CPCI System of claim 1, wherein a plurality of connectors affixed to said circuit board and said front card is coupled to said transition card via said plurality of connectors.

14. A Compact Peripheral Component Interconnect (CPCI) system including a circuit board, said CPCI system comprising:
first, second, third, fourth and fifth connectors affixed to said circuit board;
a front card coupled to a transition card via said third, fourth and fifth connectors;
a Small Computer System Interface (SCSI) bus connected to said transition card, said SCSI bus having a first end and a second end; and
an SCSI device connected said first end of said SCSI bus; and
a first time-separated power domain provided to said first, second and third connectors, said first and second connectors providing said first power domain to said front card and said third connector providing said first power domain to said transition card;
wherein said first power domain can be provided to said transition card only when said front card is connected to said third connector; and
wherein said transition card uses said first power domain to determine when to provide a termination at said second end of said SCSI bus.

15. The CPCI system of claim 14, wherein a second time-separated power domain is provided to said front card and said transition card.

16. The CPCI system of claim 15, wherein said second power domain is provided to said transition card via said third, fourth and fifth connectors.

17. The CPCI system of claim 14, wherein during normal operation when said front card is connected with said CPCI system, said front card provides the termination at said second end of said SCSI bus and said transition card does not provide the termination.

18. The CPCI system of claim 16, wherein during a period of when said front card is disconnected from said CPCI system, said transition card provides the termination at said second end of said SCSI bus.

19. A method for implementing a hot swap on a Compact Peripheral Component Interconnect (CPCI) system, comprising the steps of:
providing a first time-separated power domain to a front card;
providing said first time-separated power domain to a transition card only if said front card is coupled to said transition card;
using said transition card to provide a termination at a Small Computer System Interface (SCSI) bus connected to said transition card only if said first time-separated power domain is not being provided to said transition card; and
using said front card to provide the termination at said SCSI bus if said first time separated power domain is being provided to said transition card.

20. The method of claim 19, wherein said front card is coupled to said transition card via a circuit board.

21. The method of claim 20, wherein said front card comprises first, second, third, fourth and fifth connectors, and said front card is coupled to said transition card via said third, fourth and fifth connectors.

22. The method of claim 21, wherein said first time-separated power domain is provided to said first, second and third connectors, said first and second connectors providing said first power domain to said front card and said third connector providing said power domain to said transition card.

23. The method of claim 19, further comprising the step of providing a second time-separated power domain to said front card and said transition card.

24. The method of claim 19, wherein said SCSI bus has a first end and a second end and wherein said first end is connected to an SCSI device and said second end is connected to said transition card.
